(19) United States
(12) Patent Application Publication
(10) Pub. No.: US 2009/0022879 A1
(43) Pub. Date: Jan. 22, 2009

(54) METHOD FOR APPLYING PAINTS TO SURFACES IN A CONTROLLED, POSITION-DEPENDENT MANNER

(76) Inventors: Burkhard Bustgens, Gundelfingen (DE); Suheel Georges, Kehl (DE)

Correspondence Address: JEROME D. JACKSON (JACKSON PATENT LAW OFFICE), 211 N. UNION STREET, SUITE 100, ALEXANDRIA, VA, 22314, US

(21) Appl. No.: 11/813,009

(22) PCT Filed: Jan. 25, 2006
(86) PCT No.: PCT/DE2006/000110

§ 371 Date: Mar. 24, 2008

(30) Foreign Application Priority Data
Jan. 25, 2005 (DE) 10 2005 003 333.4

(51) Int. Cl. C23C 16/52

(52) U.S. Cl. 427/8

(57) ABSTRACT

The invention relates to a method for applying paints or varnishes to large surfaces by means of a displaceable, paint applying device which is controlled in a position-dependent manner. Said device contains a displaceable part of a real time position measuring system which is used to measure the position thereof, which supports reference marks (4) in a fixed manner. The invention is characterised in that the position of at least one reference mark (4) of the real time position measuring system is determined by means of a position measuring method, which supports positions of reference marks (4) of the real time position measuring system.

The invention relates to the technical field of applying paints to surfaces, particularly to applying decorative painted patterns to large surfaces, particularly surfaces in building construction, civil engineering, and general structural engineering according to a original image. These surfaces may be, for example, inner and outer walls, ceilings, or floors of residential and commercial buildings, but may also be, for example, the concrete surfaces of bridge, tunnel, or road constructions or walls for blocking sounds or views or for reinforcements and or related types of surfaces.

The painted patterns mentioned are made at present almost exclusively by an artist's hands and thus do not represent a 1:1 reproduction of the original image. Technical solutions include, on the one hand, modified printers: In FR 2,601,265 or in WO 00 48,841, advancing mechanisms are mounted on the surface and the printer head is guided line by line over the surface. These tools thus have the drawback that only a portion of a surface that is accessible in its entirety can be printed. Proposed in DE 195 25,528, therefore, is a printing system that is fastened to a manipulator arm and is moved along a programmed route over the surface to be printed. In this way, even individual surface elements can be printed in a flexible manner. Here, too, however, the printing of a surface of any extent is not possible in a simple manner. Proposed in WO 03 066,239, therefore, is a paint applying system that uses sensor systems in order to follow the position of a freely moved, particularly manually manipulated paint applying mechanism and to print the image information as a function of the position. Described in the embodiment examples for this are position measuring systems that are suitable for determining the position even when there are irregularities in the surface. The system makes available an array of paint applying elements, which constitute the basis for an economical printing operation. The position measuring system makes available reference marks, which are applied to the object surface prior to the start of the printing operation. In this description, position measuring systems that serve for measuring the paint applying tool during paint application are referred to as real-time position measuring systems. It is noted that, by applying many reference marks, a high coverage of the object surface can be achieved, making it possible to print around irregularities in the surface. However, with an increasing number of reference marks, the effort involved in the placing of the reference marks and, in particular, in the necessary measurement of the coordinates of the reference marks increases, which is very time-consuming, and thus the economical advantages of the method are once again lost. In the case of very large surfaces, this required time is especially long.

Therefore, the problem of the invention is to create an economical method for determining the positions of reference marks of the real-time position measuring system.

The method of the invention solves this problem by solely employing the position measuring system that is used or a related measuring system by itself. It is a method for applying paints or varnishes to large surfaces by means of a displaceable, paint applying tool, which is controlled in a position-dependent manner and contains a displaceable part of a real-time position measuring system that is used to measure the position thereof and which relies on positionally fixed reference marks, characterized in that the position of at least one reference mark of the real-time position measuring system is determined by means of a position measuring method that relies on positions of reference marks of the real-time position measuring system.

On the one hand, the determination of the positions of the reference marks by way of a position system that also relies on the reference marks that are used for position measurement of the paint applying tool frees the operator of the paint applying tool from the extensive work effort involved in manually measuring the position of the reference marks. On the other hand, this method makes it possible to determine mark positions with the same high precision offered by the highly precise position measuring system required for applying paint. As a reference value for the precision both of the position measuring system and of the mark positions, it is possible to take the magnitude of the mutual spacing of image points, namely, the pitch, which lies far below one millimeter. Such a precision cannot be achieved today by conventional measuring methods, for example, on large facade surfaces.

It is fundamentally possible by means of the method to print any surface of spatially free shape and size. The position measuring system is therefore generally capable of determining coordinates in three dimensions (position and/or rotation). In accordance therewith, the reference marks are also located freely in space, albeit in fixed position in relation to the surface. Only for reasons of simpler explanation will the following description of the invention and of the embodiment examples treat planar surfaces (which can be described in two dimensions), The coordinates of the working tool that are relevant for a printing are then the position (x, y) and the angle of rotation (phi) of the working tool in relation to the surface. The coordinate system (origin and rotation) can be chosen at will. An extension to three-dimensional surfaces is possible in a simple manner by applying known mathematical relations.

### DESCRIPTION OF THE INVENTION

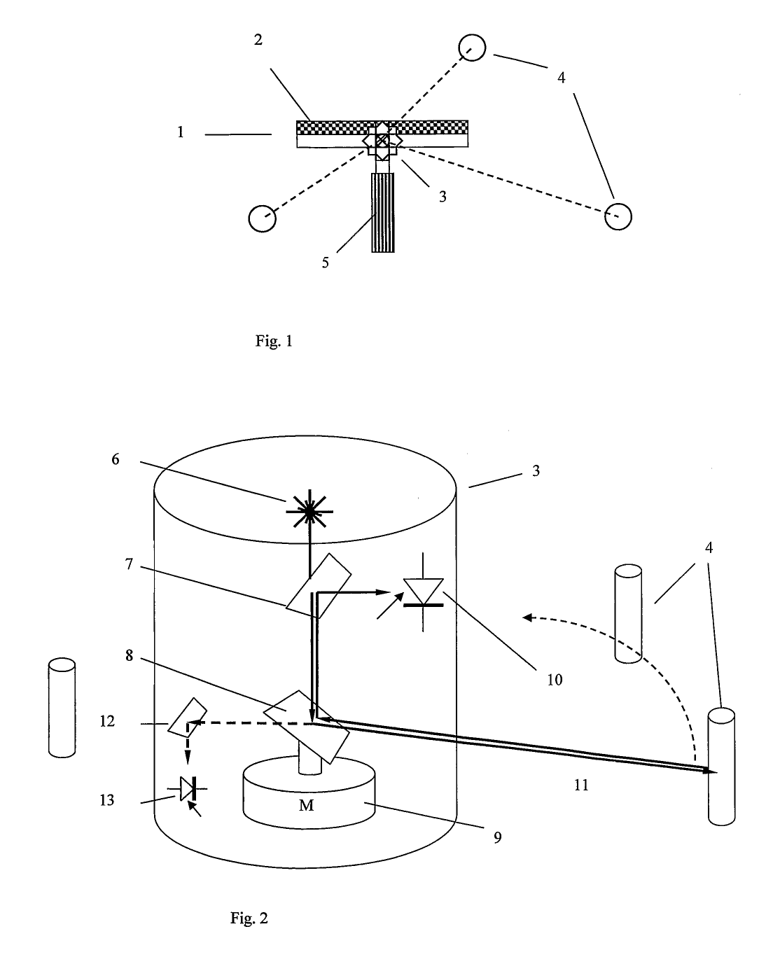

FIG. 1 depicts, by way of example, a paint applying tool of the generic type of the invention, which contains paint applying elements 2. Depicted is a hand-guided working tool, which allows a very flexible mode of operation, even at poorly accessible sites. The position measuring system of the invention is based on a displaceable part 3 and non-displaceable reference marks 4. The position measurement is based on the measurement of distances and/or of angular positions of the displaceable part of the position measuring system in relation to as many fixed reference marks as possible, applied in known position. The measuring method is based physically on the linear spread of waves of short wavelength—for example, of light, IR (e.g., thermal radiation), or ultrasound. The prior art offers technical methods and mechanisms to this end for contact-free distance measurement or angle measurement. For purposes of explanation, the measuring methods are to be categorized, for example, according to the generation of the measuring signal. In the inside-out method, the position of the displaceable part of the measuring system from its viewpoint is calculated in relation to the reference marks. In the outside-in method, the process is reversed. The measuring signal can be produced, for example, by a camera. This performs geometrically a point projection of the field of view of the camera and registers a specific spatial angle. Within this spatial angle, identified points in the image may be assigned unequivocal angles according to their location in the image, thereby affording conditions for the positional determination of these points in space. Mounted on the working tool (inside-out method), the camera is able to provide angle information concerning visible reference marks that are fixed in place; that is, the measuring information is an angular position. These reference marks display, for instance, a strong contrast to the surroundings, are lit up, or are landscape marks, that is, high-contrast features of the surroundings (here, reference marks=landscape marks). In the outside-in method, the cameras are situated in the reference marks, whereas the displaceable working tool displays, for example, a high-contrast feature. In this case, the reference marks measure the angular position of the feature on the basis of the position in the image, so that, here, too, the measuring magnitude is an angular position.

In the case of a flat surface, it is advantageous when the reference marks 4 and the displaceable part of the position measuring system 3 are situated in a plane parallel to the surface. Sufficient in this case is a single, rotating beam of light issuing from the displaceable unit (inside-out) or issuing from the respective reference marks.

Depicted as a position measuring system of the invention in FIG. 2 is a laser-based system having a laser scanner on the displaceable part of the position measuring system 3. The system operates according to the inside-out measuring method. A laser beam 11 is produced in the laser source 6, passes first through a semi-transparent mirror 7, and is deflected by means of a rotating mirror 8, driven by a rotating unit (for example, a scanner motor 9) so that it describes a full circle in a single plane. Here, for example, the reference marks 4 are provided with a retroreflecting layer, which causes an impinging laser beam to be bounced back once again in the direction of the light impingement. Accordingly, when it impinges on a reference mark 4, the rotating laser beam 11 is bounced back once again to the rotating mirror 8 and deflected in its further path through the semi-transparent mirror 7, at least in part, onto the photoreceptor 10. In the course of a single rotation of the scanner motor 9, it is thus possible by way of the photoreceptor 10 to record the light reflections issuing from the reference marks. If the scanner motor rotates at a constant speed of rotation, the analysis of the measured reflections over time affords a direct measure of the angular position of the reference marks 4 in relation to the displaceable part of the position measuring system 3. For the determination of the zero angle position, the crossing laser beam 11 can be deflected at a fixed position (for example, via a mirror 12) to a reference photodiode 13. It is noted that a measuring system for measuring the angular position can be constructed in a multiplicity of variants—for example, an incremental encoder can be used for determining the instantaneous angular position of the laser beam or active sensitive markers (and a signal transmission) can be used. The scanning time of the laser beam 11 over a reference mark of defined width can be further employed optionally for estimating the distance between the displaceable part of the position measuring system 3 and the reference mark 4.

It is noted that, in the framework of the invention, it is not necessary to employ the real-time position measuring system of the paint applying tool in order to determine the mark positions. It may require less effort for the operator, for example, to use a separate, lighter position measuring system, which, however, otherwise conforms to the function of the real-time position measuring tool of the paint applying tool.

The position measuring method used for this should instead be related in terms of measuring method to the position measuring system integrated in the paint applying tool, which is understood to mean that it also relies on reference marks for determining its own position, these reference marks being positioned at points at which the reference marks of the real-time position measuring system are positioned. An especially emphasized special case is the case when the position measuring system for determining the position of the reference marks itself relies on the very reference marks that are used by the real-time position-measuring system of the paint applying tool.

A detailed working procedure for the application of the method of the invention will be given below by way of example:

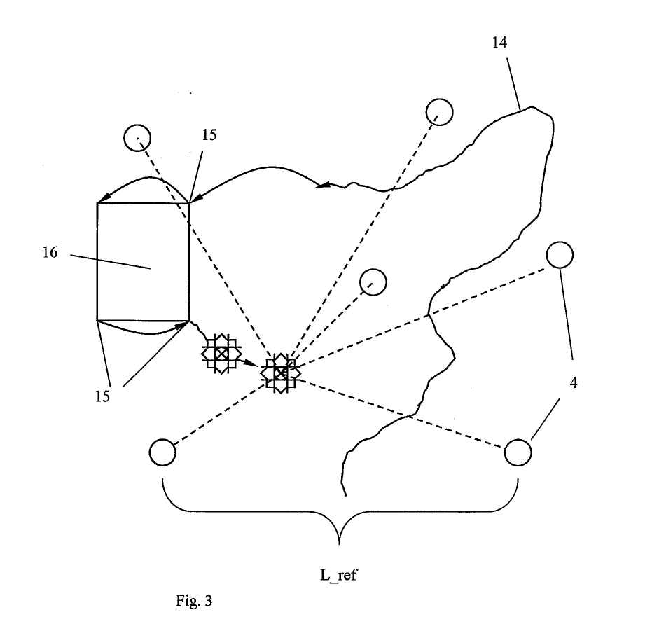

In general, the geometry of a surface to be printed is not known with sufficient precision. The working procedure begins with the application of reference marks to the surface in fixed position. In this example, a large number of reference marks are first applied over the entire work surface. The application is effected at will with respect to the position of the individual reference marks, albeit in such a way that a uniform distribution is achieved over the surface. The determination of the coordinates of the reference marks—in the case of a manual working tool—follows in a semi-automatic way. To this end, the working tool is brought into contact with the surface and moved over the surface along a trajectory 14 (see FIG. 3). The movement can take place continuously or discontinuously or else individual points—for instance, the positions of surface features 15, such as corners and edges—can be approached explicitly, as illustrated in FIG. 3 by the example of a window 16. During this operation, the distance and/or the angular position between the displaceable part of the position measuring system and the reference marks that are situated in close range are measured at a plurality of points, digitized, and stored in memory by the position measuring system. Accordingly available for each point are measurement data that can be employed in a set of defining equations for the coordinates of the point and of each reference mark. A single defining equation for a reference mark j at the position i can take the following form, by way of the example of the laser measuring system according to FIG. 2, starting from a measured angle φᵢⱼ:

φᵢⱼ−φᵢ₀=arctan 2(yᵢ−yⱼ, xᵢ−xⱼ)

Here, φ_{i,0} represents the rotational position, (xᵢ, yᵢ) represent the coordinates of the working tool at the site i, and (xⱼ, yⱼ) are the coordinates of the reference mark j.

It can be shown by means of this equation that only above a number of j=4 registered reference marks can the position of these reference marks and that of the working tool be determined. For this, at least i=8 positions must be approached and the number of equations is i×j=32. A diversity of numerical solution methods are available at present for the solution of the nonlinear system of equations, such as, for example, the Newton-Raphson method or the Gaus-Newton method in the case of a specific problem. This situation is afforded when the number of the variables to be solved matches exactly the number of equations. It is appropriate to take substantially more measurements for the position calculations, because, in this way, the precision of the calculated coordinates increases. This can be done by including as many additional marks as possible and/or though a high rate of measurement, that is, through measurements of as many points in the trajectory curve as possible. In the latter case, a truly large amount of measurement data can be obtained, so that it is appropriate to employ filtering techniques, such as Kalman filters or other tracking logarithms.

The number of measurements and equations required for the determination of all reference mark positions can be reduced by placing individual reference marks at known positions or by fixing beforehand individual relationships between the positions of the reference marks—for instance, a distance between two reference marks. This means that the position measuring system can be supported in part or completely on marks of known positions in order to determine the position of a mark that is registered by the measuring system but is still undetermined in its position. If a sufficiently large number of reference marks are determined in their position, the position of each point of the surface that can be scanned by the displaceable part of the position measuring system can be determined by means of these marks. Accordingly, it is possible to place at each point of the surface that is scanned with the displaceable part of the position measuring system an additional reference mark to which the coordinates of the point are assigned and thus to achieve a higher coverage of the surface with reference marks.

Position measuring systems that measure only angles, for example, require one or more reference distances in order to calculated unequivocal positions. These can be, for example, known distances of features of the surface, which are scanned after the reference marks are introduced by the position measuring system. However, if measures or distances between registered features are not known, a reference length can be defined in a different way. It can be, for example, the distance between at least two reference marks (see L_ref in FIG. 3). For this purpose, individual reference marks can even be placed at a known, given distance from one another by using a caliper, for example, or else the distance between at least two previously placed reference marks can be measured by using a ruler, for example. Furthermore, a reference length can be obtained by directly measuring the path of the working tool between two points or else continuously by, for example, using an incremental encoder or by measuring the speed together with a time measurement during traversal of a path on the surface. In this way, it is possible to set up, for example, mathematical auxiliary conditions with respect to the defining equations given above by way of example and to use them implicitly to solve the latter. The solution variant should not exclude the fact that, for example, a fixed given stretch of known length is scanned on the surface by the working tool for recording position information.

At one site of the surface, where the coordinates of the reference marks are known and a virtual coordinate system exists, it is possible to carry out a printing by the paint applying elements in accordance with a method such as that described in WO 03 066239. In doing so, it is assumed that there exists a rule that assigns a color to coordinates of the surface and that this rule is applied for the printing. The current coordinates of the working tool are calculated continuously during the paint application by using, for example, the algorithms described above. These algorithms further offer the possibility of continually checking the precision of the coordinates of the reference marks and of improving them. It may happen that, at points of the surface, the amount of measurement data is insufficient to calculate the position of the working tool. The cause of this may be, for example, the fact that, in areas of the surface, an insufficient number of reference marks lie within the measuring area of the position measuring system or else that the free line of sight between individual reference marks and the working tool is interrupted. In this case, reference marks can be subsequently applied and the method of the invention can be carried out once again until the coordinates of the new reference marks are determined.

If individual reference marks are applied directly on or near to the surface, these can hinder the working tool when paint is to be applied to the surroundings of these reference marks. In this case, it is fundamentally possible to fasten the reference marks via a releasable coupling or a fitting and then to remove them temporarily when the working tool approaches them. In this case, it must be ensured that there are a sufficient number of other reference marks in range of the working tool for position determination.

After the initial fastening of the reference marks, the coordinate system is then defined by determining the coordinates of the marks. For this purpose, it is not absolutely necessary that the entire working tool be moved over points of the surface, but rather parts thereof, which, however, necessarily contain the displaceable part of the position measuring system, may also be used. An independent tool, which contains the essential components of the displaceable part of the position measuring system, is also suitable for this working step.

Because the reference marks can be applied in any way, it is necessary to establish, in addition, a relationship between the virtual coordinate system, created by the reference marks, and the surface geometry, represented by surface features, such as, for example, edges and corners. This is possible by simple scanning of these points by using the working tool or the displaceable part of the position measuring system and matching them up. Obviously, it may be economical for the work procedure to apply reference marks to these surface features themselves. In this case, the reference mark coordinates and the surface features must be assigned to one another.

1-16. (canceled)

17. A method for applying paints or varnishes to large surfaces by means of a displaceable, paint applying tool, which is controlled in a position-dependent manner and contains a displaceable part of a real-time position measuring system that is used to measure its position and which relies on positionally fixed reference marks, characterized in that the position of a reference mark of the real-time position measuring system is determined by employing the real-time position measuring system or another position measuring system that relies on the reference marks,
by introducing a number of reference marks in fixed position relative to the surface and by positioning the displaceable part of the real-time position measuring system or the displaceable part of the other position measuring system at several points of the surface, and by measuring for the individual points distance and/or angular position between the displaceable part of the position measuring system employed and reference marks by means of the position measuring system employed, and by determining therefrom the position of the a reference mark,
and/or by determining the position of a point relative to the surface by means of the real-time position measuring system or the other position measuring system by relying on marks of known position, by introducing a reference mark at this position, and by assigning the measured position to the reference mark.

18. The method according to claim 17, further characterized in that the positions of two reference marks to which the real-time position measuring system or the other position measuring system refer are known.

19. The method according to claim 17, further characterized in that reference marks are introduced so that the distance between two reference marks corresponds to a pregiven value.

20. The method according claim 17, further characterized in that the reference marks are fastened via a releasable coupling, and in that the coupling is removed temporarily when the paint applying tool approaches a reference mark.

21. The method according claim 17 further characterized in that the position measuring method applied in the real-time position measuring system or in the other position measuring system is an inside-out method.

22. The method according claim 17 further characterized in that the position measuring method applied in the real-time position measuring system or in the other position measuring system is an outside-in method.

23. A use of a real-time position measuring system, which contains a rotating unit that emits light in the direction of reference marks and/or detects light emitted by reference marks for conducting the method according to claim 17
